(19) United States
(12) Patent Application Publication
(10) Pub. No.: US 2025/0361623 A1
(43) Pub. Date: Nov. 27, 2025

(54) FLEXIBLE COPPER CLAD LAMINATE

(71) Applicant: POMIRAN METALIZATION RESEARCH CO., LTD., TAOYUAN CITY (TW)

(72) Inventors: CHUNG-YI CHEN, TAOYUAN CITY (TW); HSIN-EN HUANG, TAOYUAN CITY (TW); TSANG-SHENG KUO, TAOYUAN CITY (TW); NING CHANG, TAOYUAN CITY (TW)

(73) Assignee: POMIRAN METALIZATION RESEARCH CO., LTD., TAOYUAN CITY (TW)

(21) Appl. No.: 19/182,671

(22) Filed: Apr. 18, 2025

(30) Foreign Application Priority Data
May 27, 2024 (TW) 113119526

(51) Int. Cl. C23C 28/02; C23C 18/16; C23C 18/50; C25D 3/38

(52) U.S. Cl. CPC C23C 28/023; C23C 18/1641; C23C 18/50; C25D 3/38

(57) ABSTRACT

Provides a flexible copper clad laminate, including a polyimide substrate; a nickel-copper alloy layer formed on at least one surface of the polyimide substrate by electroless plating, wherein the nickel-copper alloy layer includes nickel, copper and phosphorus, and in the nickel-copper alloy layer, the weight ratio of the copper/the nickel is greater than 1.3 and less than 2.3, and the content of the phosphorus is greater than 2.1 wt % and less than 3.0 wt %; and a copper layer formed on one surface of the nickel-copper alloy layer far away from the polyimide substrate and combined with the nickel-copper alloy layer to form a metal conducting layer. In addition, the flexible copper clad laminate is suitable for high-frequency transmission and beneficial to manufacturing a flexible circuit board suitable for the high-frequency transmission.

### CROSS-REFERENCE TO RELATED APPLICATION

This non-provisional application claims priority under 35 U.S.C. § 119(a) on Patent Application No(s).113119526 filed in Taiwan, R.O.C. on May 27, 2024, the entire contents of which are hereby incorporated by reference.

### BACKGROUND OF THE INVENTION

### 1. Field of the Invention

The present disclosure relates to a flexible copper clad laminate and particularly relates to a flexible copper clad laminate for high-frequency transmission.

### 2. Description of the Related Art

Adhesiveless flexible copper clad laminate (2L-FCCL) is mainly prepared by combining a polyimide substrate with a copper clad in a coating or sputtering or pressing mode, and is characterized by having higher heat resistance and size stability. In recent years, wet metallization has been developed, in which a nickel layer is formed on the surface of the polyimide substrate and a copper layer is electroplated on the nickel layer.

By forming the nickel layer between the copper layer and the polyimide substrate, the peeling strength between the polyimide substrate and a metal conducting layer formed by the nickel layer and the copper layer can be increased, thereby further improving the structural strength of the flexible copper clad laminate.

### BRIEF SUMMARY OF THE INVENTION

However, since the magnetic property and low conductivity of a nickel metal affect the transmission of electronic signals, a circuit conductor may cause additional insertion loss due to skin effect during high-frequency transmission.

Then if too much insertion loss occurs, the signals are not complete during the high-frequency transmission of the circuit conductor.

Therefore, in the technical field of the present disclosure, there is a space for further improvement in the flexible copper clad laminate for high-frequency transmission.

It is found by the inventors that the flexible copper clad laminate of the present disclosure does not generate resonance absorption in the frequency range of 1-4 GHz and is beneficial to manufacturing of a flexible circuit board for the high-frequency transmission. In other words, the flexible copper clad laminate of the present disclosure can reduce the insertion loss in the frequency range of 1-4 GHz by using the electroless plating method and the specific composition of a nickel-copper alloy layer. The flexible copper clad laminate suitable for the high-frequency transmission can be obtained.

In order to solve the problems, a flexible copper clad laminate of one example of the present disclosure includes a polyimide substrate; a nickel-copper alloy layer formed on at least one surface of the polyimide substrate by electroless plating, wherein the nickel-copper alloy layer includes nickel, copper and phosphorus, and in the nickel-copper alloy layer, the weight ratio of the copper/the nickel is greater than 1.3 and less than 2.3, and the content of the phosphorus is greater than 2.1 wt % and less than 3.0 wt %; and a copper layer formed on one surface of the nickel-copper alloy layer far away from the polyimide substrate and combined with the nickel-copper alloy layer to form a metal conducting layer.

In examples, the nickel-copper alloy layer is a single plating layer.

In examples, the thickness of the single-sided nickel-copper alloy layer is greater than 60 nm and less than 90 nm.

In examples, the nickel-copper alloy layer has the relative magnetic permeability of less than 1 at the frequency of 100 MHz.

In examples, under the conditions that the concentration of a metal salt of the electroless plating bath is 4.8 g/L, the concentration of a reducing agent is 20 g/L, and the temperature of the plating bath is 38° C., the nickel-copper alloy layer is formed at the plating rate greater than 0.8 nm/sec.

In examples, the sheet resistance of the nickel-copper alloy layer is less than 10 Ω/sq.

In examples, the copper layer is formed on the nickel-copper alloy layer by electroplating and has the thickness of 0.2-20 μm.

One aspect of the present disclosure is completed in view of conventional problems, and its purpose is to provide a flexible copper clad laminate suitable for high-frequency transmission.

### BRIEF DESCRIPTION OF THE DRAWINGS

FIG. 1 is a schematic cross-sectional view of a flexible copper clad laminate of an example of the present disclosure.

FIG. 2 is a manufacturing flow chart of a flexible copper clad laminate of an example of the present disclosure.

FIG. 3 is a graph showing the comparison of the insertion loss of example 1 and comparative examples 1-2 of the present disclosure.

FIG. 4A is a photograph of through hole metallization of comparative example 7 of the present disclosure.

FIG. 4B is a photograph of through hole metallization of comparative example 6 of the present disclosure.

FIG. 4C is a photograph of through hole metallization of example 1 of the present disclosure.

FIG. 5A is a photograph of a circuit of comparative example 3 of the present disclosure after etching.

FIG. 5B is a photograph of a circuit of example 1 of the present disclosure after etching.

### DETAILED DESCRIPTION OF THE INVENTION

The embodiments of the present disclosure are illustrated by the following specific examples, and other advantages and effects of the present disclosure will become apparent to those skilled in the art from the content of the disclosure of the present description. The present disclosure can be implemented or applied by other different specific examples. The various details in the present description can also be subjected to various modifications and changes without departing from the spirits and scopes of the present disclosure based on different viewpoints or applications.

Unless otherwise indicated, the terms “A-B” used in the description and claims are intended to include the meaning of “A or greater and B or less”. For example, the term “10-40 wt %” includes the meaning of “10 wt % or greater and 40 wt % or less”.

### Flexible Copper Clad Laminate

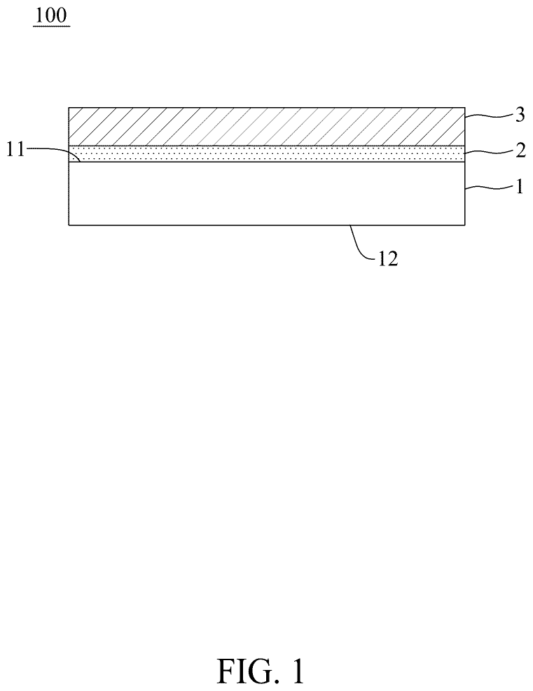

Firstly, referring to FIG. 1, FIG. 1 is a schematic cross-sectional view of a flexible copper clad laminate 100 of an example of the present disclosure. As shown in FIG. 1, the flexible copper clad laminate 100 of an example of the present disclosure includes a polyimide substrate 1; a nickel-copper alloy layer 2; and a copper layer 3. The polyimide substrate 1 includes a first surface 11 and a second surface 12, and the nickel-copper alloy layer 2 and the copper layer 3 can be combined into a metal conducting layer.

Then, as shown in FIG. 1, the nickel-copper alloy layer 2 is formed on the first surface 11 of the polyimide substrate 1, and the copper layer 3 is formed on one surface of the nickel-copper alloy layer 2 far away from the polyimide substrate 1. That is, the structure of the flexible copper clad laminate 100 is sequentially the polyimide substrate 1, the nickel-copper alloy layer 2, and the copper layer 3. In addition, the nickel-copper alloy layer 2 can also be formed on the first surface 11 and the second surface 12 of the polyimide substrate 1 at the same time. Next, the flexible copper clad laminate 100 of the present disclosure will be illustrated in detail.

### Polyimide Substrate

The polyimide substrate is a sheet/film substrate made of polyimide (PI), and the thickness thereof is may be about 5-150 μm and not particularly limited. In addition, the polyimide substrate may be made of transparent polyimide, for example, the polyimide having the light transmittance greater than 87%. Besides, the polyimide substrate may be commercially available, for example, a polyimide film made by the Taimide Technologies with the model of TX6-025.

### Nickel-Copper Alloy Layer

The nickel-copper alloy layer includes nickel, copper and phosphorus. Specifically, since a electroless plating solution includes sodium hypophosphite as a reducing agent, phosphorus is also co-deposition as one of alloy compositions during reductive deposition of nickel ions. In the present disclosure, the content of the phosphorus is greater than 2.1 wt % of the nickel-copper alloy layer and less than 3.0 wt % of the nickel-copper alloy layer, and may be controlled by compositions of the electroless plating solution and operating conditions. In addition, if the content of the phosphorus is 2.1 wt % or less of the nickel-copper alloy layer, the plating rate during electroless plating may be too slow (e.g., the plating rate is 0.8 nm/sec or less) and skip plating may occur. On the other hand, if the content of the phosphorus is 3.0 wt % or greater of the nickel-copper alloy layer, obvious metal residues may be left after an etching process in solution of H₂O₂/H₂SO₄, which may result in a problem of increased circuit width and even short circuit in the subsequent circuit manufacturing.

Then, in the nickel-copper alloy layer of the present disclosure, the weight ratio of the copper/the nickel (i.e., the weight of the copper/the weight of the nickel) is greater than 1.3 and less than 2.3. Moreover, if the weight ratio of the copper/the nickel is 1.3 or less, obvious metal residues will be left after the etching process in solution of H₂O₂/H₂SO₄; and on the other hand, if the weight ratio of the copper/the nickel is 2.3 or greater, skip plating may also occur. Further, the content of the copper in the nickel-copper alloy layer is preferably within the range of 50-65 wt %.

On the other hand, in addition to the nickel, the copper and the phosphorus, as long as the metal of the nickel-copper alloy layer is capable of co-deposition with the nickel, the metal can be appropriately added according to the desired characteristics and is not particularly limited. Specifically, the nickel-copper alloy layer of the present disclosure may further include at least one selected from the group consisting of molybdenum, tungsten, tin, chromium, and zinc, but does not include magnetic iron and cobalt.

Besides, the nickel-copper alloy layer of the present disclosure may be a single plating layer, and namely may be combined without other layers to achieve the effect of no resonance absorption in the frequency range of 1-4 GHZ, thereby further saving the manufacturing cost. In addition, the thickness of a single-sided metalized nickel-copper alloy layer is preferably greater than 60 nm and less than 90 nm, and the total thickness of the double-sided metalized nickel-copper alloy layer may be greater than 120 nm and less than 180 nm.

Then, in the present disclosure, the nickel-copper alloy layer is formed by electroless plating on at least one surface of the polyimide substrate to form a plating layer. In addition, as a specific example of the electroless plating, a roll-shaped polyimide substrate (available from the Taimide Technologies, model of TX6-025) is first subjected to a continuous hydrophilization modification treatment by a Corona treater (available from WEDGE corporation, Japan) under the operating conditions of the power of 3 kw and the speed of 3 m/min.

Besides, the electroless plating may be a conventional electroless plating method, for example, a prior application of the applicant (Application No. TW112142862, the contents of which are incorporated by reference into the present description) may be referred to, which is not particularly limited.

Then, the hydrophilized polyimide substrate is cut into a size of 20 cm*20 cm and soaked in a 2 wt % KOH solution at 40° C. for 150 s. Then, a catalyst is provided by an SLP metallization process (SLP process) of OKUNO Chemical Industries Co., Ltd. to obtain a single-sided or double-sided polyimide substrate with a palladium catalyst, wherein the palladium catalyst is from SLP-400 in the SLP series electroless nickel plating reagents.

Then, the polyimide substrate with the palladium catalyst is subject to the electroless plating to form the nickel-copper alloy layer.

### Copper Layer

The copper layer of the present disclosure is not particularly limited as long as it is a copper layer capable of forming a subsequent etched circuit. In addition, in one example, the copper layer is preferably plated on the nickel-copper alloy layer by electroplating. An electroplating solution used for the copper layer may be commercially available, for example, a copper sulfate electroplating solution (available from All-in-line Chemicals Enterprise Co., Ltd). Besides, the thickness of the copper layer is preferably 0.2-20 μm.

Specifically, electroplating the copper layer can be performed by a conventional method, for example, referring to the prior application of the applicant (Application No. TW112142862), thereby obtaining a single-sided or double-sided electroplated copper layer about 1 μm copper thick each.

Here, the thickness of the copper layer may be measured using a copper thickness meter (available from Shin-shen Co., Ltd). Specifically, an FCCL sample of 10 cm*10 cm is placed on a measurement table and the thickness of the copper layer may be measured by uniformly contacting the FCCL copper surface with tips of a four-point probe.

### Method for Manufacturing Flexible Copper Clad Laminate

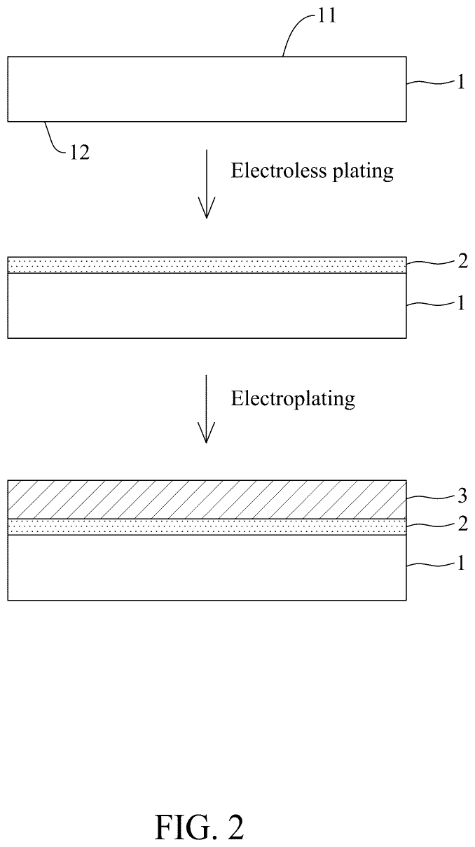

Firstly, referring to FIG. 2, FIG. 2 is a manufacturing flow chart of a flexible copper clad laminate 100 of an example of the present disclosure. As shown in FIG.

2, the method for manufacturing the flexible copper clad laminate of an example of the present disclosure includes: providing a polyimide substrate 1; forming a nickel-copper alloy layer 2 on a first surface 11 of the polyimide substrate 1 by electroless plating; and forming a copper layer 3 on one surface of the nickel-copper alloy layer 2 far away from the polyimide substrate 1 by electroplating.

Here, in an example, the nickel-copper alloy layer 2 may also be formed on the first surface 11 and the second surface 12 at the same time. In this case, the copper layers 3 are formed on the surfaces of the two nickel-copper alloy layers 2 far away from the polyimide substrate 1 respectively.

Then, the electroless plating method and the electroplating method may be conventional electroless plating method and electroplating method without limitation. Specifically, the electroless plating method and the electroplating method may be used, which are not described in detail herein.

### EXAMPLES

Hereinafter, the present disclosure will be illustrated specifically by way of examples and comparative examples, but the present disclosure is not limited to these examples and comparative examples.

### Measurement of Elemental Composition of Nickel-Copper Alloy Layer

A sample of the polyimide substrate plated with the nickel-copper alloy layer was directly placed in an SEM for vacuumizing by using a scanning electron microscope (SEM/EDS) of Jiedong Co., Ltd and under the state of no gold plating, and then the elemental composition of the nickel-copper alloy layer within the range of 200 μm*150 μm was analyzed by EDS.

### Plating Layer Residue (Etching Property)

A microscope (VK-X3000) of Taiwan Keyence was used, an etched flexible circuit board sample was directly placed on an analysis platform, and the finest circuit area (circuit width/circuit distance=25/25 μm) was observed by using a 50× optical lens to confirm the shapes and whether there were metal residues present in the outer edges.

In addition, in the present disclosure, those with no metal residues were marked as ◯, those with trace metal residues were marked as Δ, and those with obvious metal residues (under etching) were marked as X. The definition of the no metal residues meant that there was no trace at the edge of the circuit, the definition of the trace metal residues meant that the trace width at the edge of the circuit was 2 μm or less, and the definition of the obvious metal residues meant that the trace width at the edge of the circuit was greater than 2 μm.

### Insertion Loss of Circuit Board

First, a PI substrate with the thickness of 25 μm was taken, a electroless plated nickel-copper alloy was applied as a seed layer, and then a copper layer with the thickness of 12 μm was electroplated thereon to obtain a double-sided flexible copper clad laminate (FCCL). Then, the FCCL was used to manufacture a differential microstrip circuit board for testing insertion loss, wherein the circuit width was 40-50 μm, the circuit height was 20-22 μm, and the impedance control was 100 Ω=10%.

The differential microstrip circuit board for testing included two signal wires with the lengths of 2 inches and 10 inches, a cover layer was laminated on the circuit, and the surface treatment was performed on the joint by electroless nickel immersion gold (ENIG). Then, before formal testing, a network analyzer (Keysight Technologies, N5224B) was firstly used to confirm that the impedance of the set of the signal wires is within 100±5Ω, and the qualified signal wires were taken to measure the transmission loss within the frequency range of 10 MHz-43.5 GHZ. Finally, connect the measuring head to the 2-inch and 10-inch wires respectively, and measure and record the signal loss of both. Subtract the signal loss of the 2-inch wire from the signal loss of the 10-inch wire, which is the actual signal loss of the 8-inch wire after excluding connectors and other losses.

### Absorbance

Firstly, a polyimide (PI) substrate plated with a double-sided nickel-copper alloy layer with the specific thickness was taken as a sample, soaked in a H₂O₂/H₂SO₄ quick etching solution for 20 s at room temperature, taken out, washed with water, and dried. Then, the residue of the plating layer on the PI substrate was analyzed using the absorbance mode of a UV-Vis spectrophotometer (Sun-way Co., Ltd., JASCO/V-750). The un-plated PI substrate was taken as a reference and the absorbance of the etched sample at the wavelength of 500 nm was measured and compared. In addition, the higher absorbance indicated greater residual amount of the plating layer, that was, the nickel-copper alloy layer was less easily etched.

### Sheet Resistance

The PI substrate plated with the nickel-copper alloy layer was cut into a sample of 10 cm*10 cm and placed on the measurement table. The sheet resistance was measured by touching the four-point probe of the resistance analyzer (Southnorth Co., Ltd., LORESTA/MCP-T370) to the sample surface, and experimental data was an average value of 5 points.

### Thickness of Nickel-Copper Alloy Layer

An X-ray plating thickness tester (General Technologies, FISCHERSCOPE® XDL210) was used and calibrated before measuring. Then, a PI substrate with one side plated with a nickel-copper alloy layer was cut into a sample of 10 cm*10 cm and placed in a measurement area to measure the thickness of the nickel-copper alloy layer, and the experimental data was an average value of 5 points.

### Relative Magnetic Permeability at 100 MHz

An impedance analyzer (Keysight Technologies, E4991B) and a dielectric material test fixture (Keysight Technologies, 16453A) were used and calibrated before measuring. Then stack 200-300 circular-shaped plating samples with an outer diameter of 18 mm and an inner diameter of 5 mm, place them in the electrodes of the fixture, and then enter the sample size to measure the relative magnetic permeability in the frequency range of 1 kHz to 1 GHz.

### Confirmation of Quality of Through Hole Metallization

A stereoscopic microscope (URANUS Technology Co., Ltd., Motic/SMZ-171TP) was used, a sample of a electroless plated nickel-copper alloy layer was placed on a platform, and the metallization of the outer edges of through holes was observed by using a 5× optical lens to confirm whether skip plating occurs or not.

In addition, in the present disclosure, those with no PI substrate exposed at the outer edges of the through hole were regarded as good, those with a small part of the PI substrate exposed at the outer edges of the through holes were regarded as local skip plating, and those with a large part of the PI substrate exposed at the outer edges of the through holes were regarded as severe skip plating.

### Overall Evaluation

If at least one of the characteristics in Tables 1 and 3 below was X, the overall evaluation was X; and when at least one was Δ, the overall evaluation was Δ; and when all the characteristics were ◯ or conforming, the overall evaluation was ◯.

### Example 1

### Pretreatment of Polyimide Substrate

A roll-shaped polyimide substrate (available from the Taimide Technologies, model of TX6-025) was first subjected to a continuous hydrophilization modification treatment by a Corona treater (available from WEDGE Corporation, Japan) under the operating conditions of the power of 3 kw and the speed of 3 m/min. Then the hydrophilized polyimide substrate was cut into a size of 20 cm*20 cm and soaked in a 2 wt % KOH solution at 40° C. for 150 s.

### Electroless Plating of Nickel-Copper Alloy Layer

First, as described above, steps of conditioning, pre-dipping, catalyzation, and acceleration were sequentially performed on the hydrophilized polyimide substrate by an SLP metallization process to obtain a double-sided polyimide substrate with a palladium catalyst.

Next, a electroless plating solution was prepared in a 5-liter beaker (bath volume of 5 L) and included 86.0 g of nickel sulfate, 18.9 g of copper sulfate, 100 g of sodium hypophosphite (reducing agent), 300 g of sodium citrate (coordination agent), and 120 g of boric acid (buffering agent). The pH was adjusted to 8.5 with a 50 wt % NaOH solution. Then, the polyimide substrate with the palladium catalyst was soaked in the electroless plating solution and reacted at 38° C. for 90 s to make the total thickness of the double-sided plating layer was 160±10 μm. Then, taken out, washed with water and dried to form the polyimide substrate plated with the nickel-copper alloy layers (ternary alloy including nickel/copper/phosphorus) on both sides.

### Through Hole Metallization of Pre-Drilled PI Substrate

Through hole metallization of the pre-drilled PI substrate was performed as follows.
(1) Laser drilling: the PI substrate was cut into a size of A4, placed on a suction platform of a UV laser machine, and drilled to the hole diameter of 30, 50, 100, 200, and 500 μm respectively, and 100 through holes were formed at 2 cm*2 cm square for each hole diameter. Then the PI substrate was soaked in a beaker filled with a 5 wt % isopropanol (IPA) aqueous solution, subjected to ultrasonic oscillation for 5 minutes to clean the surface and the through holes of the substrate, taken out, and washed with water to perform subsequent metallization.
(2) Pretreatment: the PI substrate obtained through step (1) was soaked in a 2 wt % KOH solution at 40° C. for 150 s.
(3) Catalyst attachment: as described above, the catalyst was provided by the SLP metallization process.
(4) Electroless plating: as described above, electroless plating was performed to plate a nickel-copper alloy layer on the PI substrate.

### Electroplating of Copper Layer

The PI substrate subjected to through hole metallization was fixed with a stainless steel frame, firstly soaked in a 3 wt % H₂SO₄ solution for 1 minute to clean the surface, and then plated with copper in an electroplating bath. The electroplating area was 15 cm*15 cm, the electroplating solution included 150 g/L of H₂SO₄, 120 g/L of CuSO₄, chlorine ions with the concentration of 50 ppm, and an appropriate amount of a brightener and a leveler. The power-on conditions were current of 6 A, voltage of 3 V, and time of 2 minutes. The electroplated PI substrate was taken out, washed with water, and dried to obtain a flexible copper clad laminate with a copper thickness of about 1 μm on both sides.

### Manufacturing of Circuit

Then, referring to the prior application of the applicant (Application No. TW112142862), the flexible copper clad laminate obtained in example 1 was sequentially subjected to a conventional semi-additive process such as pretreatment, lamination, exposure, development, copper plating, stripping, and quick etching, thereby correspondingly preparing a flexible circuit board having the circuit width/circuit distance=25/25 μm.

The quick etching was fixing a semi-finished circuit product that have completed pattern electroplating with a plastic frame and placing that on a quick etching line (available from Fujichem Precision Machineries Co., Ltd) to perform bottom metal etching. The quick etching solution included 5 wt % of sulfuric acid, 10 wt % of hydrogen peroxide, copper ions with the concentration lower than 30 g/L, and an appropriate amount of an etching additive (available from JCU Taiwan Corporation), the operation speed was 0.9 m/min, and the flexible circuit board with fine circuits was obtained after the operation was completed.

Finally, the concentration of the metal ions in the electroless plating solution, the composition and the characteristics of the nickel-copper alloy layer of example 1 were set forth in Tables 1-2. In addition, the measurement methods of the characteristics were referred as above, which was not described in detail herein.

### Comparative Example 1

A electroless plating solution was prepared in a 5-liter beaker (bath volume of 5 L) and included 107.5 g of nickel sulfate, 100 g of sodium hypophosphite, 200 g of sodium citrate, and 120 g of boric acid. The pH was adjusted to 8.5 with a 50 wt % NaOH solution. Then, the polyimide substrate with the palladium catalyst on both sides was soaked in the electroless plating solution, reacted for 95 s at the temperature of 38° C., taken out, washed with water, and dried, thereby forming the polyimide substrate with both sides plated with the nickel/phosphorus alloy with the total thickness about 160 μm±10 μm.

Then, the metallization, the electroplating, the circuit manufacturing, etc. of the pre-drilled PI substrate were performed in the same manner as those in example 1, thereby obtaining the flexible copper clad laminate and the flexible circuit board of comparative example 1.

### Comparative Examples 2-9 and Examples 2-5

Then, in the same manner as in example 1, the weight ratio of copper/nickel and the content of phosphorus in the electroless plating solution were changed based on the following Table 1, thereby obtaining the flexible copper clad laminate and the flexible circuit board of comparative examples 2-9 and examples 2-5. In addition, the concentrations of the metal ions in the electroless plating solutions, the compositions and the characteristics of the nickel-copper alloy layers of comparative examples 2-9 and examples 2-5 were set forth in Tables 1-2.

TABLE 1

| | Concentrations of | | | | | | | | | | | | | |
|---|---|---|---|---|---|---|---|---|---|---|---|---|---|---|
| | main components | | | | | | | Characteristics of nickel-copper alloy layer | | | | | | |
| | in plating solution | | | Weight composition | | | | | | | | Relative | | |
| | (g/L) | | | of nickel-copper | | | | Etching | | | Through | magnetic | FPC | |
| | | | Coordi- | alloy layer | | | | property | | Plating | hole | perme- | insertion | Overall |
| Experi- | | | nation | (wt %) | | | Cu/Ni | (10% H₂O₂ + | | rate | metal- | ability | loss@2 GHz | evalu- |
| ment No. | Ni²⁺ | Cu²⁺ | agent | Ni | Cu | P | ratio | 5% H₂SO₄) | | (nm/sec) | lization | @100 MHz | (dB/cm) | ation |
| Example 1 | 3.84 | 0.96 | 60 | 34.0 | 63.5 | 2.5 | 1.9 | No | ◯ | 0.89 | Good | 0.997 | 0.182 | ◯ |
| | | | | | | | | residues | | | | | | |
| Example 2 | 3.98 | 0.82 | 60 | 37.6 | 59.6 | 2.8 | 1.6 | No | ◯ | 0.97 | Good | 0.995 | 0.184 | ◯ |
| | | | | | | | | residues | | | | | | |
| Example 3 | 3.94 | 0.86 | 60 | 38.3 | 59.0 | 2.7 | 1.5 | No | ◯ | 0.95 | Good | 0.998 | 0.183 | ◯ |
| | | | | | | | | residues | | | | | | |
| Example 4 | 3.89 | 0.91 | 60 | 36.2 | 61.2 | 2.6 | 1.7 | No | ◯ | 0.93 | Good | 0.995 | 0.178 | ◯ |
| | | | | | | | | residues | | | | | | |
| Example 5 | 3.79 | 1.01 | 60 | 33.2 | 64.5 | 2.3 | 1.9 | No | ◯ | 0.86 | Good | 0.996 | 0.179 | ◯ |
| | | | | | | | | residues | | | | | | |
| Compar- | 4.80 | 0.00 | 40 | 91.4 | 0.0 | 9.2 | 0.0 | Under | X | 0.85 | Good | 21.127 | 0.374 | X |
| ative | | | | | | | | etching | | | | | | |
| example 1 | | | | | | | | | | | | | | |
| Compar- | 4.56 | 0.24 | 40 | 76.1 | 17.0 | 6.9 | 0.2 | Under | X | 0.99 | Good | 0.997 | 0.189 | X |
| ative | | | | | | | | etching | | | | | | |
| example 2 | | | | | | | | | | | | | | |
| Compar- | 4.32 | 0.48 | 40 | 60.2 | 35.3 | 4.5 | 0.6 | Under | X | 1.02 | Good | 0.994 | 0.185 | X |
| ative | | | | | | | | etching | | | | | | |
| example 3 | | | | | | | | | | | | | | |
| Compar- | 4.08 | 0.72 | 40 | 47.4 | 49.2 | 3.4 | 1.0 | Under | X | 1.04 | Good | 0.995 | 0.182 | X |
| ative | | | | | | | | etching | | | | | | |
| example 4 | | | | | | | | | | | | | | |
| Compar- | 3.84 | 0.96 | 40 | 43.3 | 53.7 | 3.0 | 1.2 | Trace | Δ | 1.01 | Good | 0.996 | 0.181 | Δ |
| ative | | | | | | | | residues | | | | | | |
| example 5 | | | | | | | | | | | | | | |
| Compar- | 3.84 | 0.96 | 70 | 29.3 | 68.7 | 2.0 | 2.3 | No | ◯ | 0.63 | Local | 0.998 | — | X |
| ative | | | | | | | | residues | | | skip | | | |
| example 6 | | | | | | | | | | | plating | | | |
| Compar- | 3.84 | 0.96 | 80 | 24.1 | 74.0 | 1.9 | 3.1 | No | ◯ | 0.32 | Severe | 0.996 | — | X |
| ative | | | | | | | | residues | | | skip | | | |
| example 7 | | | | | | | | | | | plating | | | |
| Compar- | 4.03 | 0.77 | 60 | 42.6 | 54.2 | 3.1 | 1.3 | Trace | Δ | 1.03 | Good | 0.997 | 0.183 | Δ |
| ative | | | | | | | | residues | | | | | | |
| example 8 | | | | | | | | | | | | | | |
| Compar- | 3.74 | 1.06 | 60 | 26.8 | 71.1 | 2.1 | 2.7 | No | ◯ | 0.71 | Local | 0.995 | — | X |
| ative | | | | | | | | residues | | | skip | | | |
| example 9 | | | | | | | | | | | plating | | | |

TABLE 2

| | | Total | | PI substrate | |
|---|---|---|---|---|---|
| | | thickness of | | after etching | |
| | Plating | double-sided | Sheet | Absor- | |
| Exper- | time | plating | resistance | bance | Metal |
| iment No. | (sec) | layer (nm) | (Ω/sq) | (%) | residue |
| Example 1 | 90 | 161 | 6.7 | 0.230 | No |
| | | | | | residues |
| Example 2 | 85 | 165 | 6.2 | 0.245 | No |
| | | | | | residues |
| Example 3 | 85 | 162 | 6.6 | 0.241 | No |
| | | | | | residues |
| Example 4 | 85 | 158 | 6.5 | 0.235 | No |
| | | | | | residues |
| Example 5 | 95 | 163 | 6.3 | 0.215 | No |
| | | | | | residues |
| Comparative | 95 | 162 | 7.5 | 1.250 | Under |
| example 1 | | | | | etching |
| Comparative | 80 | 158 | 7.2 | 0.750 | Under |
| example 2 | | | | | etching |
| Comparative | 80 | 163 | 7.0 | 0.435 | Under |
| example 3 | | | | | etching |
| Comparative | 80 | 166 | 6.9 | 0.352 | Under |
| example 4 | | | | | etching |
| Comparative | 80 | 162 | 6.9 | 0.279 | Trace |
| example 5 | | | | | residues |
| Comparative | 120 | 151 | 6.7 | 0.205 | No |
| example 6 | | | | | residues |
| Comparative | 250 | 160 | 6.4 | 0.203 | No |
| example 7 | | | | | residues |
| Comparative | 75 | 155 | 6.9 | 0.294 | Trace |
| example 8 | | | | | residues |
| Comparative | 110 | 156 | 6.3 | 0.212 | No |
| example 9 | | | | | residues |

First, it can be seen from Table 1 that since in all examples 1-5 use electroless plating to form the nickel-copper alloy layer, and the weight ratio of the Cu/the Ni in the nickel-copper alloy layer was greater than 1.3 and less than 2.3, and the content of phosphorus was more than 2.1 wt % and less than 3.0 wt %, such that the nickel-copper alloy layer had no residues after etching and the insertion loss of the flexible printed circuit manufactured at the frequency of 2 GHz was 0.2 dB/cm or less, i.e., the insertion loss was reduced. In addition, it can be seen from Table 1, the relative magnetic permeability of the nickel-copper alloy layer of all examples 1-5 at a frequency of 100 MHz is less than 1, which means that the plating layers is non-magnetic and there will be no additional insertion loss during high-frequency transmission.

Then, since the weight ratios of the Cu/the Ni in the nickel-copper alloy layers of comparative examples 1-5 and 8 were 1.3 or less and the content of the phosphorus was 3.0 wt % or greater, trace residues or under etching will be observed after etching in comparative examples 1-5 and 8, which was non-conforming. Besides, since the weight ratios of the Cu/the Ni in the nickel-copper alloy layers of comparative examples 6-7, and 9 were 2.3 or greater and the content of the phosphorus was 2.1 wt % or less, local skip plating or severe skip plating may occur during the through hole metallization and the insertion loss cannot be measured.

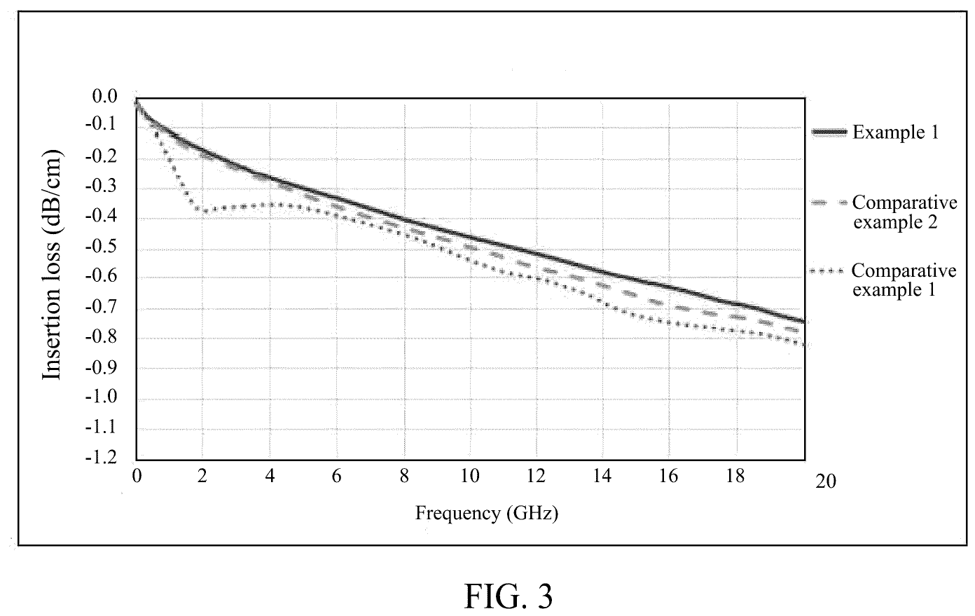

Here, referring to FIG. 3, FIG. 3 was a graph showing the comparison of the insertion loss of example 1 and comparative examples 1-2 of the present disclosure. It can be seen from FIG. 3, example 1 of the present disclosure had lower insertion loss compared with comparative examples 1-2. In particular, compared with comparative example 1, example 1 of the present disclosure may greatly reduce the insertion loss in the frequency range of 1-4 GHz.

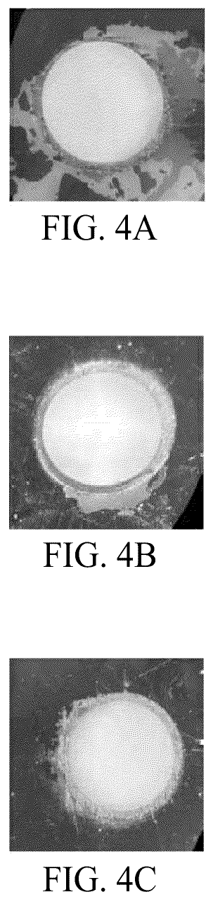

Besides, referring to FIG. 4A to FIG. 4C, FIG. 4A was a photograph of through hole metallization of comparative example 7 of the present disclosure; FIG. 4B was a photograph of through hole metallization of comparative example 6 of the present disclosure; and FIG. 4C was a photograph of through hole metallization of example 1 of the present disclosure. In addition, it can be seen from FIG. 4A that in comparative example 7, most of the PI substrate was exposed at the outer edges of the through holes, which was severe skip plating; it can be seen from FIG. 4B, in comparative example 6, a small part of the PI substrate was exposed at the outer edges of the through holes, which was local skip plating; and it can be seen from FIG. 4C, in example 1, no PI substrate was exposed at the outer edges of the through holes, which was good plating.

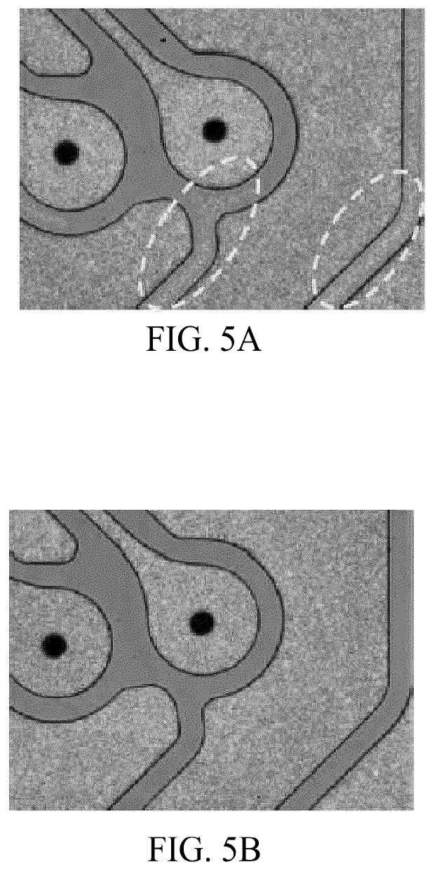

Then, referring to FIG. 5A to FIG. 5B, FIG. 5A was a photograph of a circuit of comparative example 3 of the present disclosure after etching; and FIG. 5B was a photograph of a circuit of example 1 of the present disclosure after etching. In addition, it can be seen from FIG. 5A that since the content of the phosphorus in comparative example 3 was too high, nickel-copper alloy layer residues were left between the circuits (see the dotted line-encircled areas). On the other hand, it can be seen from FIG. 5B that no metal residues were left between the circuits in example 1.

Then, as shown in Table 1, under the conditions that the concentration of a metal salt (concentrations of nickel ions+copper ions) of the electroless plating bath was 4.8 g/L, the concentration of a reducing agent (sodium hypophosphite) was 20 g/L, and the temperature of the plating bath was 38° C., the nickel-copper alloy layers of examples 1-5 were all formed at the plating rate greater than 0.8 nm/sec. On the other hand, since the contents of the phosphorus in comparative examples 6-7 and 9 were too low, the plating rates were all less than 0.8 nm/sec, and ideal nickel-copper alloy layers could not be obtained.

Besides, it can be seen from Table 2 that the higher absorbance indicated more residual amount of the plating layer, i.e., the nickel-copper alloy layer was less easily etched and may be left on the PI substrate. Specifically, since the absorbances of comparative examples 1-5 and 8 were 0.27% or greater, trace residues or under etching may occur. In addition, it can be seen from Table 2 that the total thickness of the double-sided plated nickel copper alloy layers of the examples and comparative examples was set to the range of greater than 120 nm and less than 180 nm, that was, the thickness of the single-sided plating layer was set to the range of greater than 60 nm and less than 90 nm, thereby obtaining a nickel-copper alloy layer having the desired sheet resistance (e.g., less than 10 Ω/sq). In the following, in test examples, the thickness of the plating layer was discussed.

### Test Examples

First, as test examples 1-6, based on the plating layer composition of example 1 (i.e., 34.0 wt % of Ni, 63.5 wt % of Cu, and 2.5 wt % of P) and with reference to Table 3 below, the nickel-copper alloy layers of different plating thicknesses were formed. In addition, the characteristics of the nickel-copper alloy layers of test examples 1-6 were measured based on the above measurement method and shown in Table 3.

TABLE 3

| | Total | | | | | |
|---|---|---|---|---|---|---|
| | thickness of | | | | | |
| | double-sided | Sheet | Continuous | PI substrate after etching | | |
| Experiment | plating layer | resistance | roll-to-roll | Absorbance | Metal | Overall |
| No. | (nm) | (Ω/sq) | electroplating | (%) | residue | evaluation |
| Test | 206 | 4.8 | Good | 0.740 | Under | X |
| example 1 | | | | | etching | |
| Test | 182 | 5.5 | Good | 0.315 | Trace | Δ |
| example 2 | | | | | residues | |
| Test | 161 | 6.7 | Good | 0.230 | No | ◯ |
| example 3 | | | | | residues | |
| Test | 137 | 8.1 | Good | 0.185 | No | ◯ |
| example 4 | | | | | residues | |
| Test | 116 | 11.2 | Slightly high | 0.166 | No | Δ |
| example 5 | | | voltage and | | residues | |
| | | | pay attention to | | | |
| | | | operation | | | |
| Test | 98 | 14.3 | Difficult power | 0.151 | No | X |
| example 6 | | | transmission | | residues | |
| | | | and | | | |
| | | | cannot produce | | | |

As shown in Table 3, since the total thickness of the double-sided plated nickel-copper alloy layers of test examples 1-2 was greater than 180 nm, although the sheet resistance of test examples 1-2 was less than 10 Ω/sq, the absorbance of the PI substrate after etching was too high, and under etching or trace residues may occur. In addition, since the total thickness of the double-sided plated nickel-copper alloy layers of test examples 5-6 was less than 120 nm, although the PI substrate of test examples 5-6 had no metal residues after etching, the sheet resistance was too high (greater than 10 Ω/sq) and there was an operation risk of an excessively high voltage when performing continuous roll-to-roll electroplating.

On the other hand, since the total thickness of the double-sided plated nickel-copper alloy layers of test examples 3-4 was in the range of greater than 120 nm and less than 180 nm, test examples 3-4 had the sheet resistance of less than 10 Ω/sq, and the etched PI substrate had no metal residues, which belonged to preferred test examples. Therefore, it can be seen from Tables 2-3, the thickness of the single-sided nickel-copper alloy layer was preferably greater than 60 nm and less than 90 nm, and the double-sided total thickness was preferably greater than 120 nm and less than 180 nm.

The present disclosure can reduce the insertion loss in the frequency range of 1-4 GHz by using the electroless plating method and the specific composition of the nickel-copper alloy layer, and obtain the flexible copper clad laminate and flexible circuit board suitable for high-frequency transmission.

In addition, in the preferred examples of the present disclosure, by controlling the thickness of the nickel-copper alloy layer, the nickel-copper alloy layer with the ideal sheet resistance and with no metal residues after etching can be obtained to manufacture the flexible copper clad laminate and the flexible circuit board suitable for high-frequency transmission.

In addition, in the preferred examples of the present disclosure, by controlling the plating rate of the electroless plating, the nickel-copper alloy layer with good through hole metallization can be obtained to manufacture the flexible copper clad laminate and the flexible circuit board suitable for high-frequency transmission.

The present disclosure is not limited to the above examples, various modifications can be made within the scope of the claims, and the examples obtained by appropriately combining the technical means disclosed in the different examples are also included in the technical scope of the present disclosure.

While the present disclosure has been described by means of specific embodiments, numerous modifications and variations could be made thereto by those skilled in the art without departing from the scope and spirit of the present disclosure set forth in the claims.

What is claimed is:

1. A flexible copper clad laminate, comprising:
a polyimide substrate;
a nickel-copper alloy layer formed on at least one surface of the polyimide substrate by electroless plating, wherein the nickel-copper alloy layer comprises nickel, copper and phosphorus, and in the nickel-copper alloy layer, the weight ratio of the copper/the nickel is greater than 1.3 and less than 2.3, and the content of the phosphorus is greater than 2.1 wt % and less than 3.0 wt %; and
a copper layer formed on one surface of the nickel-copper alloy layer far away from the polyimide substrate and combined with the nickel-copper alloy layer to form a metal conducting layer.

2. The flexible copper clad laminate according to claim 1, wherein the nickel-copper alloy layer is a single plating layer.

3. The flexible copper clad laminate according to claim 1, wherein the thickness of the single-sided nickel-copper alloy layer is greater than 60 nm and less than 90 nm.

4. The flexible copper clad laminate according to claim 1, wherein the nickel-copper alloy layer has the relative magnetic permeability of less than 1 at the frequency of 100 MHz.

5. The flexible copper clad laminate according to claim 1, wherein under the conditions that the concentration of a metal salt of the electroless plating bath is 4.8 g/L, the concentration of a reducing agent is 20 g/L, and the temperature of the plating bath is 38° C., the nickel-copper alloy layer is formed at the plating rate greater than 0.8 nm/sec.

6. The flexible copper clad laminate according to claim 1, wherein the sheet resistance of the nickel-copper alloy layer is less than 10 Ω/sq.

7. The flexible copper clad laminate according to claim 1, wherein the copper layer is formed on the nickel-copper alloy layer by electroplating and has the thickness of 0.2-20 μm.

8. The flexible copper clad laminate according to claim 2, wherein the copper layer is formed on the nickel-copper alloy layer by electroplating and has the thickness of 0.2-20 μm.

9. The flexible copper clad laminate according to claim 3, wherein the copper layer is formed on the nickel-copper alloy layer by electroplating and has the thickness of 0.2-20 μm.

10. The flexible copper clad laminate according to claim 4, wherein the copper layer is formed on the nickel-copper alloy layer by electroplating and has the thickness of 0.2-20 μm.

11. The flexible copper clad laminate according to claim 5, wherein the copper layer is formed on the nickel-copper alloy layer by electroplating and has the thickness of 0.2-20 μm.

12. The flexible copper clad laminate according to claim 6, wherein the copper layer is formed on the nickel-copper alloy layer by electroplating and has the thickness of 0.2-20 μm.
